(19) United States
(12) Patent Application Publication
(10) Pub. No.: US 2025/0334807 A1
(43) Pub. Date: Oct. 30, 2025

(54) Dual-face photosensitive lens assembly and wearable smart device using the same

(71) Applicant: Asphetek Solution (Chengdu) Ltd., Chengdu (CN)

(72) Inventors: CHUNG-CHIAO HO, Hsinchu (TW); CHUNG-WU LIU, Hsinchu (TW); YU-PI KUO, Hsinchu (TW)

(73) Assignee: Asphetek Solution (Chengdu) Ltd., Chengdu (TW)

(21) Appl. No.: 18/792,862

(22) Filed: Aug. 2, 2024

(30) Foreign Application Priority Data
Apr. 25, 2024 (CN) 202410508003.X

(51) Int. Cl. G02B 27/01; H01L 27/146

(52) U.S. Cl. CPC G02B 27/0172; H10F 39/8063; H10F 39/811

(57) ABSTRACT

A dual-face photosensitive lens assembly and wearable smart device. The Dual-face photosensitive lens assembly includes a first perspective window and a second perspective window, the dual-face photosensitive lens assembly further includes a flexible circuit board, a first sensor chipset, and a second sensor chipset. The flexible circuit board is disposed between the first perspective window and the second perspective window, the flexible circuit board includes a circuit substrate, and the flexible circuit board includes a third perspective window opened through the circuit board. The first light-sensitive chipset is electrically connected to the circuit board via a solder ball, and the first light-sensitive chipset includes a first chip. The second sensor chipset is located on the side of the first sensor chipset away from the flexible circuit board, the second sensor chipset is electrically connected to the flexible circuit board through wires, the second sensor chipset includes a second chip.

### FIELD

The subject matter relates to the field of optical technology, and in particular, to dual-face photosensitive lens assembly and a wearable smart device using the same.

### BACKGROUND

AR (Augmented Reality), VR (Virtual Reality), and MR (Mixed Reality) are three different virtual reality technologies that have different characteristics in how they interact with the real world. AR technology enhances the user's perception by overlaying virtual images, information, or scenes on top of the real world; the user can see the real-world environment and superimpose virtual elements on top of it, such as text, images. 3D VR technology places the user completely in the virtual world through devices such as enclosed head-mounted displays (HMDs); the user perceives and interacts with the virtual environment without having to perceive the real world. VR technology typically provides a highly immersive experience that can completely change the user's perception and experience. MR technology interacts virtual elements with the real world in real time, allowing the two to coexist in the same scene; the user can see and perceive the real world; users can see and perceive the real world and interact with virtual objects on it. MR technology provides a more integrated and interactive experience, blending virtual and reality more deeply than AR.

AR, VR and MR are three different virtual reality technologies whose functions can be realized with the help of wearable smart devices. In order to realize the functions of AR, VR and MR, wearable smart devices need to be equipped with a large number of image processing chip components for imaging and eye tracking functions, which can cause the quality of the wearable smart device to increase but may make the wearing experience of the wearable smart device poor. How to solve the above problems is a matter for the skilled person of the art to consider.

### SUMMARY

In order to solve the problems in the prior art, embodiments of the present application provide a dual-face photosensitive lens assembly and a wearable smart device applying the same.

Embodiments of the present application provide a dual-face photosensitive lens assembly comprises a first perspective window and a second perspective window. The dual-face photosensitive lens assembly further comprises a flexible circuit board, a first sensor chipset and a second sensor chipset. The flexible circuit board provided between the first perspective window and the second perspective window, the flexible circuit board comprises a circuit board, a third perspective window open through the circuit board. The first sensor chipset is electrically connected to the circuit substrate by a solder ball, the first sensor chipset comprises a first chip, the first chip is light-sensitive through the first perspective window and the third perspective window. The second sensor chipset is provided on the side of the first sensor chipset away from the flexible circuit board, the second sensor chipset is electrically connected to the flexible circuit board by means of wires, the second sensor chipset comprises a second chip, the second chip is light-sensitive through the second see-through window.

In one embodiment, the first sensor chipset comprises a first surface, the first chip is arranged on the first surface, the first surface is provided towards the flexible circuit board, and the solder ball is arranged on the first surface.

In an embodiment, the first sensor chipset further comprises a substrate, the first chip is disposed in the substrate, and a material of the substrate comprises silicon.

In an embodiment, the first sensor chipset further comprises a second surface, the first surface and the second surface are disposed on two sides of the first sensor chipset abutting each other, the second surface is disposed towards the second perspective window, and the second sensor chipset is disposed on the second surface.

In an embodiment, the first surface is filled with filler between the first surface and the flexible circuit board.

In one embodiment, the second photoreceptor chip set further comprises a wireframe, the second chip is disposed in the wireframe, the second chip is electrically connected to the wireframe, and the wireframe is electrically connected to the circuit substrate via the wires.

In an embodiment, the dual-face photosensitive lens assembly further comprises a housing, the housing is opened with an accommodating cavity; the flexible circuit board, the first sensor chipset and the second sensor chipset are disposed in the accommodating cavity; the flexible circuit board, the first sensor chipset and the second sensor chipset are disposed in the accommodating cavity.

In an embodiment, the dual-face photosensitive lens assembly further comprises a first filter and a second filter, the first filter is arranged between the first photo-sensitive chip set and the first perspective window, the first filter is located on the side of the flexible circuit board away from the first photo-sensitive chipset, the first filter covers the third perspective window, and the second filter is located between the second photo-sensitive chip set and the second perspective window.

In an embodiment, the dual-face photosensitive lens assembly further comprises a first lens assembly and a second lens assembly, the first lens assembly is disposed between the first filter and the first perspective window, and the second lens assembly is disposed between the second filter and the second perspective window.

Embodiments of the present application also provide a wearable smart device, the wearable smart device comprising a main part and a dual-face photosensitive lens assembly as described in any one of the foregoing embodiments. Wherein the main part comprises a first light-transmitting surface and a second light-transmitting surface disposed back-to-back, the dual-face photosensitive lens assembly is disposed between the first light-transmitting surface and the second light-transmitting surface, the first perspective window is disposed corresponding to the first light-transmitting surface, and the second perspective window is disposed corresponding to the second light-transmitting surface.

It is understood that the dual-face photosensitive lens assembly provided in this application has a first sensor chipset and a second sensor chipset stacked, and the first sensor chipset and the second sensor chipset are connected to a flexible circuit board to realize electrical signal interaction through different packaging methods. The first sensor chipset senses light through the first perspective window and the third perspective window, and the second chip senses light through the second perspective window, and the first sensor chipset and the second sensor chipset are able to sense and process light in at least two different directions, so as to realize that a dual-face photosensitive lens assembly senses light in a plurality of directions, thereby reducing the use of the number of dual-face photosensitive lens assembly, and realizing the weight reduction and cost reduction of the wearable smart device. The device can reduce the number of dual-face photosensitive lens assembly, thus realizing the weight and cost reduction of wearable smart devices.

### BRIEF DESCRIPTION OF THE DRAWINGS

FIG. 1 shows a schematic view of a dual-face photosensitive lens assembly.

FIG. 2 shows a schematic view of a wearable smart device.

### DETAILED DESCRIPTION

The following description will refer to the accompanying drawings for a more complete description of the present application. Exemplary embodiments of the present application are shown in the accompanying drawings. However, the present application can be implemented in many different forms and should not be construed as limited to the exemplary embodiments set forth herein. These exemplary embodiments are provided to make the present application thorough and complete and to adequately convey the scope of the present application to those skilled in the art. Similar accompanying drawings are labeled to indicate the same or similar components. The terminology used herein is used only for the purpose of describing particular exemplary embodiments and is not intended to limit the present application. As used herein, the singular forms “one,” “a,” and “the” are intended to include the plural form as well, unless the context clearly indicates otherwise. In addition, when used herein, the words “including” and/or “comprising” and/or “having”, integers, steps, operations, components and/or assemblies do not exclude the presence or addition of one or more other features, regions, integers, steps, operations, components and/or groups thereof. Unless otherwise defined, all terms used herein, including technical and scientific terms, have the same meaning as commonly understood by those of ordinary skill in the art to which this application belongs. Furthermore, unless expressly defined in the text, terms such as those defined in general-purpose dictionaries should be construed as having a meaning consistent with their meaning in the relevant art and in the contents of this application, and will not be construed as having an idealized or overly formalized meaning.

In general, AR, VR and MR are three different virtual reality technologies whose functions can be realized with the help of wearable smart devices. In order to realize the functions of AR, VR and MR, wearable smart devices need to be equipped with a large number of image processing chip components for imaging and eye tracking functions, which can cause the quality of the wearable smart device to increase and make the wearing experience of the wearable smart device poorer.

Correspondingly, the Dual-face photosensitive lens assembly includes a first perspective window and a second perspective window, and the Dual-face photosensitive lens assembly further includes a flexible circuit board, a first sensor chipset, and a second sensor chipset. The flexible circuit board is disposed between the first perspective window and the second perspective window, the flexible circuit board includes a circuit substrate, and the flexible circuit board includes a third perspective window opened through the circuit board. The first light-sensitive chipset is electrically connected to the circuit board via a solder ball, and the first light-sensitive chipset includes a first chip that senses light through the first perspective window and the third perspective window. The second sensor chipset is located on the side of the first sensor chipset away from the flexible circuit board, the second sensor chipset is electrically connected to the flexible circuit board through wires, the second sensor chipset includes a second chip, and the second chip is light sensitive through the second perspective window. The wearable smart device includes a main part and a dual-face photosensitive lens assembly, the main part includes a first light-transmitting surface and a second light-transmitting surface disposed back-to-back, the dual-face photosensitive lens assembly is disposed between the first light-transmitting surface and the second light-transmitting surface, the first view-through window is disposed corresponding to the first light-transmitting surface, and the second view-through window is disposed corresponding to the second light-transmitting surface.

Accordingly, the dual-face photosensitive lens assembly is provided in the present application has a stacked first sensor chipset and a second sensor chipset, and the first sensor chipset or the second sensor chipset is connected to the flexible circuit board to realize the electrical signal interaction through different packaging methods. The first sensor chipset senses light through the first perspective window and the third perspective window. The second chip senses light through the second perspective window. The first sensor chipset and the second sensor chipset are able to sense and process light in at least two different directions, realizing that a dual-face photosensitive lens assembly senses light in multiple directions, thereby reducing the use of the dual-face photosensitive lens assembly. This reduces the number of dual-face photosensitive lens assembly used, and realizes weight reduction and cost reduction of the wearable smart device.

The following will describe exemplary embodiments in conjunction with the accompanying drawings. It is to be noted that the components depicted with reference to the accompanying drawings are not necessarily to scale; and identical or similar components will be given the same or similar attachment markings or similar technical terms.

Specific embodiments of the present application are described in further detail below with reference to the accompanying drawings.

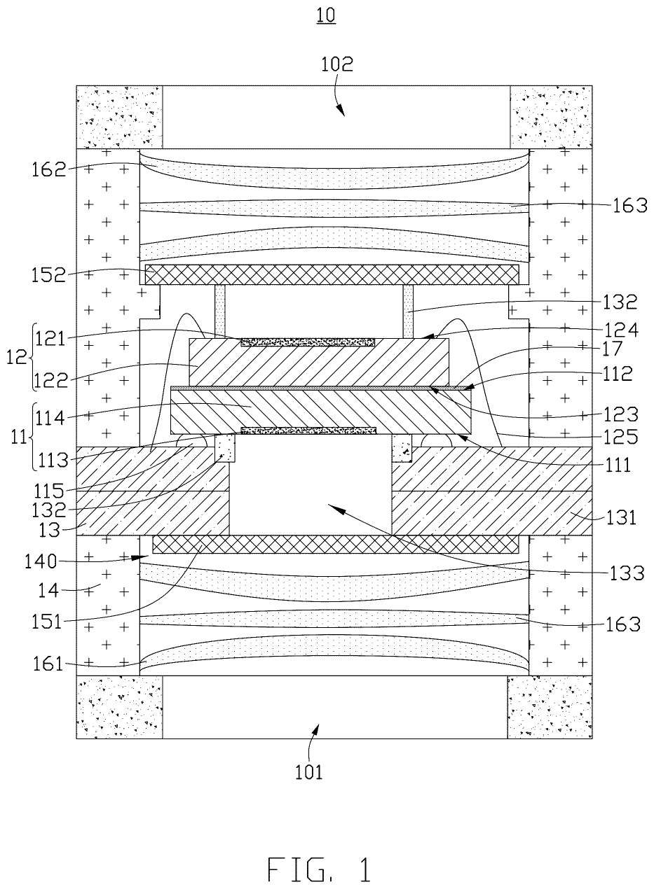

As shown in FIG. 1, a dual-face photosensitive lens assembly 10 includes a first perspective window 101 and a second perspective window 102, the dual-face photosensitive lens assembly 10 also includes a flexible circuit board 13, a first sensor chipset 11, and a second sensor chipset 12. The flexible circuit board 13, the first sensor chipset 11, and the second sensor chipset 12 are provided inside the housing 14.

In an embodiment, the flexible circuit board 13 is disposed between the first perspective window 101 and the second perspective window 102. The flexible circuit board 13 includes a circuit substrate 131, the flexible circuit board 13 includes a third perspective window 133. The third perspective window 133 runs through the circuit substrate 131. The first photosensitive chip set 11 is electrically connected to the circuit substrate 131 through the solder ball 115. The first photosensitive chip set 11 includes a first chip 113, and the first chip 113 senses light through the first perspective window 101 and the third perspective window 133. The second sensor chipset 12 is located on the side of the first sensor chipset 11 away from the flexible circuit board 13. The second sensor chipset 12 is electrically connected to the flexible circuit board 13 through the wires 125. The second sensor chipset 12 includes the second chip 121, and the second chip 121 senses light through the second perspective window 102.

It is understood that the dual-face photosensitive lens assembly 10 is provided in the present application has a stacked first sensor chipset 11 and a second sensor chipset 12, and the first sensor chipset 11 or the second sensor chipset 12 is connected to the flexible circuit board 13 to realize the electrical signal interaction through different packaging methods. The first sensor chipset 11 senses light through the first perspective window 101 and the third perspective window 133. The second chip 121 senses light through the second perspective window 102. The first sensor chipset 11 and the second sensor chipset 12 are able to sense and process light in at least two different directions, realizing that a dual-face photosensitive lens assembly 10 senses light in multiple directions, thereby reducing the use of the dual-face photosensitive lens assembly 10. This reduces the number of dual-face photosensitive lens assembly 10 used, and realizes weight reduction and cost reduction of the wearable smart device 1.

In an embodiment, the dual-face photosensitive lens assembly 10 further includes a housing 14, the housing 14 is provided with an accommodating cavity 140, and the accommodating cavity 140 is located inside the housing 14. The flexible circuit board 13, the first sensor chipset 11, and the second sensor chipset 12 are disposed in the accommodating cavity 140. The first perspective window 101 and the second perspective window 102 are disposed on opposite sides of the housing 14, and the housing 14 includes a light-shielding material.

In this embodiment, the housing 14 includes a light shielding material for shielding the surrounding light. The first perspective window 101 and the second perspective window 102 are each spatially connected to the accommodating cavity 140, so that light can be irradiated through the first perspective window 101 and the second perspective window 102 to the accommodating cavity 140. So that the first sensor chipset 11 and the second sensor chipset 12 sense light in a predetermined direction.

In an embodiment, the dual-face photosensitive lens assembly 10 further includes a first filter 151 and a second filter 152. The first filter 151 is located between the first sensor chipset 11 and the first perspective window 101, the first filter 151 is located on the side of the flexible circuit board 13 away from the first sensor chipset 11, and the first filter 151 covers the third perspective window 133. The second filter 152 is located between the second sensor chipset 12 and the second perspective window 102.

The first filter 151 is used to modulate the light irradiating the first sensor chipset 11. The first filter 151 is spaced apart from the first sensor chipset 11 by the flexible circuit board 13. The thickness of the first filter 151 may be 0.1 mm to 1.1 mm. The second filter 152 is used to modulate the light irradiating the second sensor chipset 12. The distance from the second filter 152 to the second sensor chipset 12 may be 0.15 mm to 0.3 mm, and the thickness of the second filter 152 may be 0.1 mm to 1.1 mm. The distance between the second filter 152 and the second sensor chipset 12 may be from 0.15 mm to 0.3 mm. The thickness of the flexible circuit board 13 may be from 0.1 mm to 1.1 mm.

In an embodiment, the dual-face photosensitive lens assembly 10 further includes a first lens assembly 161 and a second lens assembly 162. The first lens assembly 161 is disposed between the first filter 151 and the first perspective window 101. The second lens assembly 162 is disposed between the second filter 152 and the second perspective window 102.

In this embodiment, the first lens assembly 161 and the second lens assembly 162 are limited and fixed by the housing 14. The housing 14 may incorporate a mirror holder (not shown), and the first lens assembly 161 and the second lens assembly 162 are each housed by one of the mirror holders, so that the first lens assembly 161 and the second lens assembly 162 may be actuated to thereby achieve focal length adjustment.

It will be appreciated that the first lens assembly 161 may include a plurality of spaced-apart lenses 163. The plurality of lenses 163 is capable of being actuated to cause a change in their distance from each other, or to cause a change in the distance of the first lens assembly 161 in relation to the first filter 151, and the range of the focusing margin between the first lens assembly 161 and the first filter 151 being from 0.5 mm to 0.3 mm. The second lens assembly 162 may also include a plurality of spaced apart lenses 163, the plurality of lenses 163 is capable of being actuated to cause a change in their distance from each other or to cause a change in the distance of the second lens assembly 162 in relation to the second filter 152. The range of the focusing margin between the second lens assembly 162 and the second filter 152 being 0.5 mm to 0.3 mm.

In an embodiment, the flexible circuit board 13 is disposed in the middle of the dual-face photosensitive lens assembly 10. A portion of the flexible circuit board 13 is disposed in the interior of the accommodating cavity 140, and another portion of the flexible circuit board 13 extends to the exterior of the housing 14. The thickness of the flexible circuit board 13 may range from 0.4 mm to 1.2 mm.

It is understood that the circuit substrate 131 may be a functional body of the flexible circuit board 13, with conductive lines (not shown in the figure) embedded in the circuit substrate 131. The circuit substrate 131 may also be provided with an active element or a passive element for an arithmetic function or a transmission function to be performed. The third perspective window 133 is provided through the circuit substrate 131. The direction of penetration of the third perspective window 133 through the circuit substrate 131 is parallel to or coincides with the direction of the line between the first perspective window 101 and the second perspective window 102. The light irradiated into the interior of the housing 14 through the first perspective window 101 can continue to pass through the third perspective window 133 to be sensed by the first sensor chipset 11.

In an embodiment, the first sensor chipset 11 includes a first surface 111, the first surface 111 is disposed toward the flexible circuit board 13. The first chip 113 is disposed on the first surface 111 and a solder ball 115 is disposed on the first surface 111.

It is understood that the first chip 113 of the first sensor chipset 11 is arranged on the same side as the solder ball 115. On the one hand, this facilitates the connection of the first sensor chipset 11 to the flexible circuit board 13; on the other hand, it enables the other side of the first sensor chipset 11 to be used for setting the second sensor chipset 12.

In an embodiment, the first sensor chipset 11 further includes a substrate 114, the first chip 113 is arranged on the substrate 114, and the substrate 114 is made of a material including silicon. The first chip 113 may be a chip capable of sensing light and performing image processing, such as CMOS or CCD, for example, and the substrate 114 may be a wafer.

It will be appreciated that the first sensor chipset 11 may be fabricated by a CSP packaging process.

In one embodiment, the first surface 111 is filled with filler 132 between the first surface 111 and the flexible circuit board 13. The filler 132 may be a blackout filler, and the filler 132 may be disposed surround the third perspective window 133.

In an embodiment, the number of solder balls 115 may be a plurality, and the plurality of solder balls 115 are provided between the first surface 111 and the flexible circuit board 13. The ball diameter of the individual solder balls 115 ranges from 0.06 mm to 0.2 mm. The ball spacing between adjacent solder balls 115 ranges from 4 mil to 14 mil.

In an embodiment, the first sensor chipset 11 further includes a second surface 112, and the first surface 111 and the second surface 112 are disposed on opposite sides of the first sensor chipset 11. The second surface 112 is disposed toward the second perspective window 102, and the second sensor chipset 12 is disposed on the second surface 112.

In this embodiment, a functional layer 17 is also provided between the first sensor chipset 11 and the second sensor chipset 12. The functions of the functional layer 17 comprise: light shading, bonding, and heat dissipation. The functional layer 17 is used to make the first sensor chipset 11 and the second sensor chipset 12 form an integrated body.

In an embodiment, the second photoreceptor chip set 12 further includes a wire frame 122, and the second chip 121 is disposed in the wire frame 122. The second chip 121 is electrically coupled to the wire frame 122, and the wire frame 122 is electrically coupled to the circuit substrate 131 via the lead wires 125.

In this embodiment, the second sensor chipset 12 includes a third surface 123 and a fourth surface 124 disposed back-to-back. The third surface 123 is connected to the second surface 112 via the functional layer 17. The fourth surface 124 is disposed toward the second perspective window 102. The second chip 121 is disposed on the fourth surface 124. The second chip 121 may be a chip capable of sensing light and performing image processing, such as a CMOS or a CCD, for example.

In this embodiment, the second chip 121 is arranged on a surface of the wire frame 122 back from the first sensor chipset 11. The second chip 121 is electrically connected to the wire frame 122. The wires 125 are electrically connected to the pins of the wire frame 122 corresponding to the fourth surface 124. The wires 125 are further electrically connected to the flexible circuit board 13 across the first sensor chipset 11 and the second sensor chipset 12.

It will be appreciated that the second sensor chipset 12 may be fabricated by a COB packaging process.

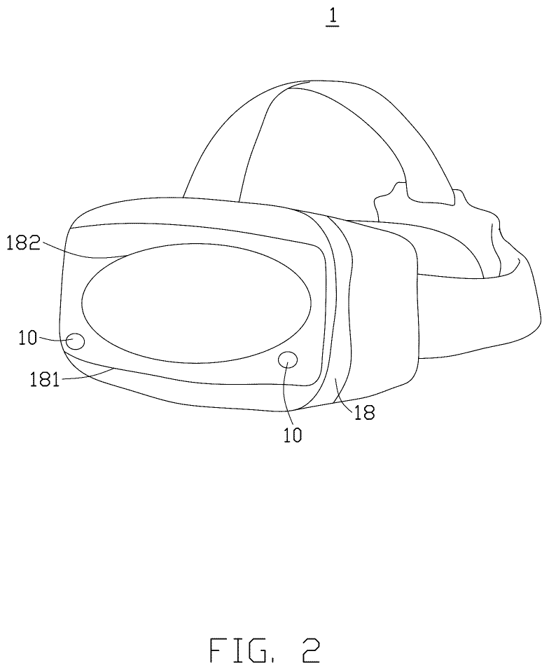

As further shown in FIG. 2, embodiments of the present application also provide a wearable smart device 1, the wearable smart device 1 includes a main part 18 and a dual-face photosensitive lens assembly 10 as in any of the preceding embodiments. The main part 18 includes a first light-transmitting surface 181 and a second light-transmitting surface 182 provided back-to-back. The dual-face photosensitive lens assembly 10 is arranged between the first light-transmitting surface 181 and the second light-transmitting surface 182. The first perspective window 101 is provided corresponding to the first light-transmitting surface 181, and a second perspective window 102 is provided corresponding to the second light-transmitting surface 182.

Understandably, the first sensor chipset 11 and the second sensor chipset 12 are provided corresponding to the first light-transmitting surface 181 and the second light-transmitting surface 182. The wearable smart device 1 is capable of sensing light irradiated into the wearable smart device 1 by the first light-transmitting surface 181 and the second light-transmitting surface 182 by means of a single dual-face photosensitive lens assembly 10. By optimizing the structure of the dual-face photosensitive lens assembly 10, the number of image processing chip components in the wearable smart device 1 is reduced, the weight of the wearable smart device 1 is reduced, and the wearable smart device 1 installed with the dual-face photosensitive lens assembly 10 is made lighter.

Above, specific embodiments of the present application are described with reference to the accompanying drawings. However, those of ordinary skill in the art can understand that various changes and substitutions can be made to the specific embodiments of the present application without departing from the spirit and scope of the present application. These changes and substitutions fall within the scope of the present application.

What is claimed is:

1. A dual-face photosensitive lens assembly comprising:
a first perspective window and a second perspective window;
a flexible circuit board provided between the first perspective window and the second perspective window, the flexible circuit board comprising a circuit board, a third perspective window opening through the circuit board;
a first sensor chipset electrically connected to the circuit substrate by a solder ball, the first sensor chipset comprising a first chip, the first chip being light-sensitive through the first perspective window and the third perspective window; and
a second sensor chipset provided on a side of the first sensor chipset away from the flexible circuit board, the second sensor chipset being electrically connected to the flexible circuit board by means of wires, the second sensor chipset comprising a second chip, the second chip being light-sensitive through the second see-through window.

2. The dual-face photosensitive lens assembly of claim 1, wherein the first sensor chipset comprises a first surface, the first chip is arranged on the first surface, the first surface is provided towards the flexible circuit board, and the solder ball is arranged on the first surface.

3. The dual-face photosensitive lens assembly of claim 2, wherein the first sensor chipset further comprises a substrate, the first chip is disposed in the substrate, and a material of the substrate comprises silicon.

4. The dual-face photosensitive lens assembly of claim 2, wherein the first sensor chipset further comprises a second surface, the first surface and the second surface are disposed on two sides of the first sensor chipset abutting each other, the second surface is disposed towards the second perspective window, and the second sensor chipset is disposed on the second surface.

5. The dual-face photosensitive lens assembly of claim 2, wherein the first surface is filled with filler between the first surface and the flexible circuit board.

6. The dual-face photosensitive lens assembly of claim 1, wherein the second photoreceptor chip set further comprises a wireframe, the second chip is disposed in the wireframe, the second chip is electrically connected to the wireframe, and the wireframe is electrically connected to the circuit substrate via the wires.

7. The Dual-face photosensitive lens assembly of claim 1, further comprising a housing, wherein the housing is open with an accommodating cavity; the flexible circuit board, the first sensor chipset and the second sensor chipset are disposed in the accommodating cavity.

8. The Dual-face photosensitive lens assembly of claim 7, wherein the first perspective window and the second perspective window are located on two different sides of the housing, the housing comprises a light-shielding material.

9. The Dual-face photosensitive lens assembly of claim 1, wherein the dual-face photosensitive lens assembly further comprises a first filter and a second filter, the first filter is arranged between the first photo-sensitive chip set and the first perspective window, the first filter is located on the side of the flexible circuit board away from the first photo-sensitive chipset, the first filter covers the third perspective window, and the second filter is located between the second photo-sensitive chip set and the second perspective window.

10. The dual-face photosensitive lens assembly of claim 8, wherein the dual-face photosensitive lens assembly further comprises a first lens assembly and a second lens assembly, the first lens assembly is disposed between the first filter and the first perspective window, and the second lens assembly is disposed between the second filter and the second perspective window.

11. A wearable smart device comprising:
a dual-face photosensitive lens assembly comprising:
a first perspective window and a second perspective window;
a flexible circuit board provided between the first perspective window and the second perspective window, the flexible circuit board comprising a circuit board, a third perspective window opening through the circuit board;
a first sensor chipset electrically connected to the circuit substrate by a solder ball, the first sensor chipset comprising a first chip, the first chip being light-sensitive through the first perspective window and the third perspective window;
a second sensor chipset provided on a side of the first sensor chipset away from the flexible circuit board, the second sensor chipset being electrically connected to the flexible circuit board by means of wires, the second sensor chipset comprising a second chip, the second chip being light-sensitive through the second see-through window; and
the wearable smart device further comprising:
a main part, wherein the main part comprises a first light-transmitting surface and a second light-transmitting surface disposed back-to-back, the dual-face photosensitive lens assembly is disposed between the first light-transmitting surface and the second light-transmitting surface, the first perspective window is disposed corresponding to the first light-transmitting surface, and the second perspective window is disposed corresponding to the second light-transmitting surface.

12. The wearable smart device of claim 11, wherein the first sensor chipset comprises a first surface, the first chip is arranged on the first surface, the first surface is provided towards the flexible circuit board, and the solder ball is arranged on the first surface.

13. The wearable smart device of claim 12, wherein the first sensor chipset further comprises a substrate, the first chip is disposed in the substrate, and a material of the substrate comprises silicon.

14. The wearable smart device of claim 12, wherein the first sensor chipset further comprises a second surface, the first surface and the second surface are disposed on two sides of the first sensor chipset abutting each other, the second surface is disposed towards the second perspective window, and the second sensor chipset is disposed on the second surface.

15. The wearable smart device of claim 12, wherein the first surface is filled with filler between the first surface and the flexible circuit board.

16. The wearable smart device of claim 11, herein the second photoreceptor chip set further comprises a wireframe, the second chip is disposed in the wireframe, the second chip is electrically connected to the wireframe, and the wireframe is electrically connected to the circuit substrate via the wires.

17. The wearable smart device of claim 11, further comprising a housing, wherein the housing is open with an accommodating cavity; the flexible circuit board, the first sensor chipset and the second sensor chipset are disposed in the accommodating cavity.

18. The wearable smart device of claim 17, wherein the first perspective window and the second perspective window are located on two different sides of the housing, the housing comprises a light-shielding material.

19. The wearable smart device of claim 11, wherein the dual-face photosensitive lens assembly further comprises a first filter and a second filter, the first filter is arranged between the first photo-sensitive chip set and the first perspective window, the first filter is located on the side of the flexible circuit board away from the first photo-sensitive chipset, the first filter covers the third perspective window, and the second filter is located between the second photo-sensitive chip set and the second perspective window.

20. The wearable smart device of claim 11, wherein the dual-face photosensitive lens assembly further comprises a first lens assembly and a second lens assembly, the first lens assembly is disposed between the first filter and the first perspective window, and the second lens assembly is disposed between the second filter and the second perspective window.
